(19) United States
(12) Patent Application Publication
(10) Pub. No.: US 2004/0084305 A1
(43) Pub. Date: May 6, 2004

(54) Sputtering system and manufacturing method of thin film

(75) Inventors: Kunihiko Fukuchi, Kanagawa (JP); Akihiko Koura, Kanagawa (JP); Tetsunori Maruyama, Kanagawa (JP); Toru Takayama, Kanagawa (JP)

Correspondence Address: NIXON PEABODY, LLP, 401 9TH STREET, NW, SUITE 900, WASINGTON, DC, 20004-2128, US

(73) Assignee: Semiconductor Energy Laboratory Co., Ltd., Atsugi-shi (JP)

(21) Appl. No.: 10/690,635

(22) Filed: Oct. 23, 2003

(30) Foreign Application Priority Data
Oct. 25, 2002 (JP) 2002-311970

(51) Int. Cl. C23C 14/32

(52) U.S. Cl. 204/298.02; 204/192.1

(57) ABSTRACT

It is an object to provide a sputtering system that enables forming a high-quality thin film including no impurity, and it is also an object of the present invention to provide a method for manufacturing a high-quality thin film with the sputtering system.

The present invention provides a sputtering system including a target material and a part coated with a spray material including the same material as the target material. The present invention also provides a method for manufacturing a thin film including one of a target material, oxide of the target material, and nitride of the target material, which includes preparing a sputtering system including the target material and a part coated with a spray material including the same material as the target material, and applying high-frequency power in an atmosphere including rare gas.

### BACKGROUND OF THE INVENTION

1. Field of the Invention

The present invention relates to a sputtering system, and also relates to a method for manufacturing a thin film with sputtering.

2. Description of the Related Arts

In these days, the development of a technique has proceeded. In the technique, a transistor, typically a thin film transistor (TFT) is formed on an insulating surface and a pixel with a combination such as the transistor and an EL element is arranged in a matrix-shape to configure a screen for displaying information. The pixel has an element including a thin film or an electrode formed with sputtering, CVD, or the like.

In order to form a high-quality thin film with sputtering, there is a sputtering system including a reaction chamber, a hydrogen cylinder, a vacuum pump, a substrate holder, and a semiconductor target facing the substrate holder with a distance of 90 mm or more, (For example, pages 2 and 3 of Japanese Patent Laid-Open 2001-144017).

When plasma is used to utilize a chemical or physical reaction in conventional plasma CVD or sputtering, a thin film with an unfavorable characteristic is formed due to various causes such as dust generation in the process forming the film, which causes production yield lowered.

In addition, when a film formed with the sputtering is analyzed, impurities such as iron (Fe), nickel (Ni), and chromium (Cr) are detected. There are considerable causes for the detected impurities, such as micro-arc discharge (local and instantaneous abnormal discharge in plasma) is generated between a target and a target shield and between the target and a contamination plate to generate minute dust (particle) 1) due to peeling of a deposited film on a wall in a chamber, 2) due to generation of plasma also in the vicinity of the target shield and the contamination plate, and 3) due to environmental contamination. In particular, a high-quality film including no impurity is required as silicon that has a role as an active layer in a TFT since characteristics of the TFT are affected.

### SUMMARY OF THE INVENTION

In view of the above problems, it is an object of the present invention to provide a sputtering system that enables forming a high-quality thin film including no impurity, and it is also an object of the present invention to provide a method for manufacturing a high-quality thin film with the sputtering system.

In order to suppress impurities generated from surfaces of parts such as a target shield, a contamination plate (hereinafter referred to as a shield collectively), a backing plate, a substrate holder, and a shutter, and a wall in a chamber, the present invention provides a sputtering system in which the surfaces of the parts and the wall are coated with a spray material including one of the same material as a target material, oxide of the target material, and nitride of the target material. For example, a semiconductor material, typically silicon, is used as the target material to provide a sputtering system in which the surfaces of the parts and the wall are coated with the spray material including one of the semiconductor material, oxide of the semiconductor material, and nitride of the semiconductor material.

It is noted that it is unnecessary that all of the surfaces of the parts and the wall are coated with the spray material, and only a portion exposed to plasma may be coated with the spray material. Alternatively, the surface of only the target shield, the surface of only the contamination plate, or the surfaces of only the target shield and the contamination plate may be coated with the spray material.

The present invention also provides a sputtering system including a target material and a part coated with a spray material including the same material as the target material, in which one of the same material as the spray material, oxide of the spray material, and nitride of the spray material is included in a thin film formed on a substrate provided to face the target material. For example, the present invention provides a sputtering system in which a semiconductor material, typically silicon, is used as the target material, a surface of the part is coated with one of the semiconductor material, oxide of the semiconductor material, and nitride of the semiconductor material, and one of the same material as the semiconductor material, oxide of the semiconductor material, and nitride of the semiconductor material is included in a thin film formed on a substrate provided to face the target material.

In addition, the present invention provides a method for manufacturing a thin film including one of the same material as a target material, oxide of the target material, and nitride of the target material, which includes preparing a sputtering system including the target material, typically silicon, and a part coated with a spray material including the same material as the target material, and applying high-frequency power in an atmosphere including rare gas.

When a thin film is formed of semiconductor, it is necessary that the target material and the spray material include the same material (semiconductor). When a thin film is formed of oxide of a semiconductor material, it is necessary that the target material and the spray material include one of the semiconductor material and oxide of the semiconductor material. When a thin film is formed of nitride of a semiconductor material, it is necessary that the target material and the spray material include one of the semiconductor material and nitride of the semiconductor material.

As set forth above, in the present invention in which a spray material is provided, it is possible to prevent a material of a shield from flying in all direction from a surface of a part such as the shield. According to the present invention, there is no adverse affect on a formed thin film if the material of the shield is mixed in the formed thin film. Accordingly, it is possible, according to the present invention, to provide a sputtering system for forming a high-quality thin film including no impurity, and to provide a method for manufacturing a high-quality thin film with a sputtering system according to the present invention. In addition, according to the present invention, it is possible to form a high-quality thin film with a high yield, and furthermore to improve productivity of an element using the thin film.

### BREIF DESCRIPTION OF THE DRAWINGS

In the accompanying drawings:

FIG. 1 is a diagram showing a sputtering system according to the present invention;

FIG. 2 is a diagram showing a multi-chamber system;

FIG. 3 is a graph showing experimental data;

FIG. 4 is a graph showing experimental data; and

FIG. 5 is a diagram showing a sectional view of a light emitting device.

### DESCRIPTION OF THE PREFERRED EMBODIMENTS

[Embodiment Mode]

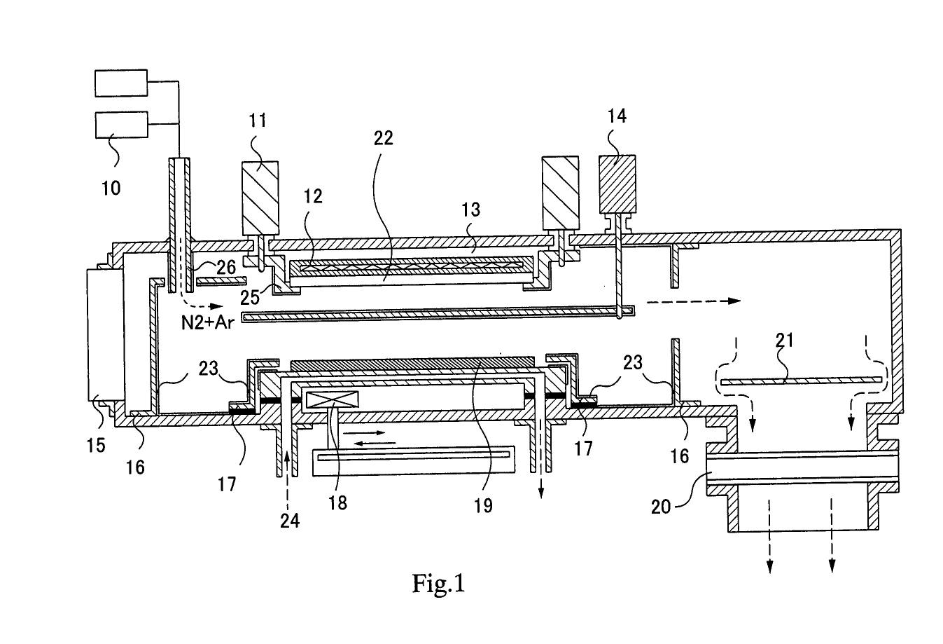

With reference to FIG. 1, an explanation will be given on a configuration of a sputtering system according to the present invention.

A target 19 is cooled (water-cooled) by a cooling medium 24 through a backing plate. A circular motion or a linear motion of a permanent magnet 18 in a direction parallel to a surface of the target makes it possible to form a film with a high uniformity of thickness on a surface of a facing substrate 22. A shutter 14 is opened and closed before and after starting deposition to prevent a film from being formed in an unstable state of plasma at the beginning of discharge.

A substrate retaining means 11 has a holder 25 moved up and down to set and fix substrate in a backside plate 13. In the backside plate 13, a sheath heater is mounted as a heating means 12, and further heated rare gas is introduced from a backside of the substrate 22 to improve uniformity in heat (not shown in the figure). From a gas introducing means 10, gas for forming a film is introduced in addition to rare gas through a gas introducing tube 26, and pressure in the chamber is controlled with a conductance valve 20. A current plate 21 is provided for rectifying current of sputtering gas in the chamber. The target is connected to a high-frequency power source, and high-frequency power is applied to perform sputtering. A gate valve 15 is used for connecting with another deposition chamber when the sputtering system is mounted into a multitasking manufacturing system provided with a plurality of treatment chambers.

A contamination plate 16 and a target shield 17 are arranged in the vicinity of the substrate 22 and the target 19 to prevent an inner wall of the chamber from being contaminated due to flying sputtered particles of the target 19 in all directions. For the contamination plate 16 and the target shield 17, stainless is generally used.

In the present embodiment mode, surfaces of the parts such as the backing plate, the shutter 14, the contamination plate 16, the target shield 17, and the inner wall of the chamber are coated with a spray material. Specifically, coating is performed with known puttering such as plasma spraying to obtain a thickness from 10 to 300 μm (preferably, from 50 to 150 μm). It is noted that it is unnecessary that all of the surfaces of the parts and the wall are coated with the spray material, and only a portion exposed to plasma may be coated with the spray material. Alternatively, the surface of only the target shield, the surface of only the contamination plate, or the surfaces of only the target shield and the contamination plate may be coated with the spray material.

In the embodiment mode, high-frequency power is applied in an atmosphere including rare gas to perform deposition with sputtering. In the case of forming a silicon oxide film, for example, silicon is used as the target, a shield coated with a spray material of silicon is used, and high-frequency power is applied in an atmosphere including oxygen or an atmosphere including oxygen and rare gas. In the case of forming a silicon nitride film, silicon is used as the target, a shield coated with the spray material of silicon is used, and high-frequency power is applied in an atmosphere including nitrogen or an atmosphere including nitrogen and rare gas.

It is noted that it is preferable to apply high-frequency power in order to generate and maintain discharge at low voltage since silicon with higher specific resistance, compared to metal, is used as the target, and a power frequency from 1 MHz to 120 MHz, preferably from 10 MHz to 60 MHz, is applied. It can be expected to form a dense film with less damage to the substrate since a chemical reaction becomes prior in the mechanism of deposition as the frequency is increased. The deposition may be performed at a room temperature without heating the substrate 22 especially. When the substrate 22 is heated at a temperature from 100 to 300° C., preferably from 150 to 200° C., in order to more enhance adhesiveness to the substrate, favorable adhesiveness can be obtained.

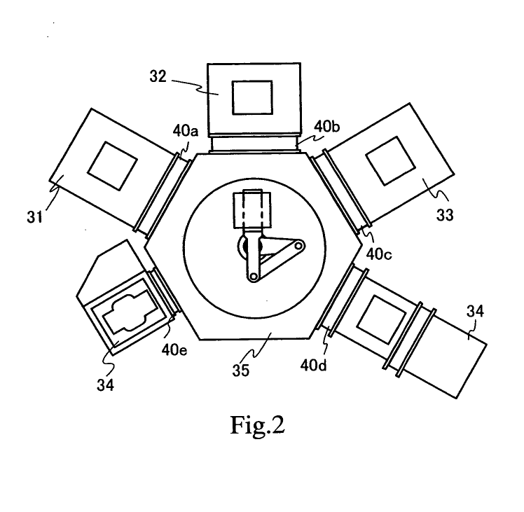

Further, FIG. 2 shows a multi-chamber system in which first to third deposition chambers 31 to 33, an unloading chamber 34 for taking a substrate out, and a loading chamber 36 are arranged with a centered transferring chamber 35. The sputtering system shown in FIG. 1 is arranged in any of the first to third deposition chambers 31 to 33. The transferring chamber 35 is connected to the first to third deposition chambers 31 to 33, the unloading chamber 34, and the loading chamber 36 through transferring gates 40a to 40e. The multi-chamber system is kept in reduced pressure at deposition.

In the embodiment mode, a magnetron sputtering system is given as an example. The present invention is applicable to not only the magnetron sputtering system but also other sputtering systems such as a sputtering system for ion beam sputtering.

[Embodiment 1]

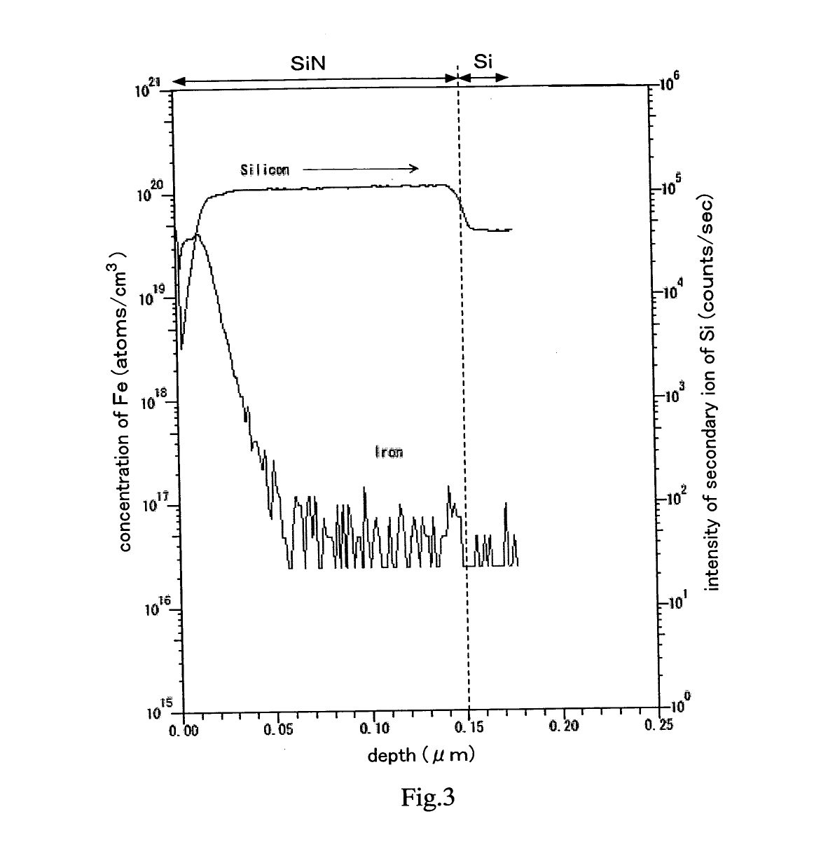

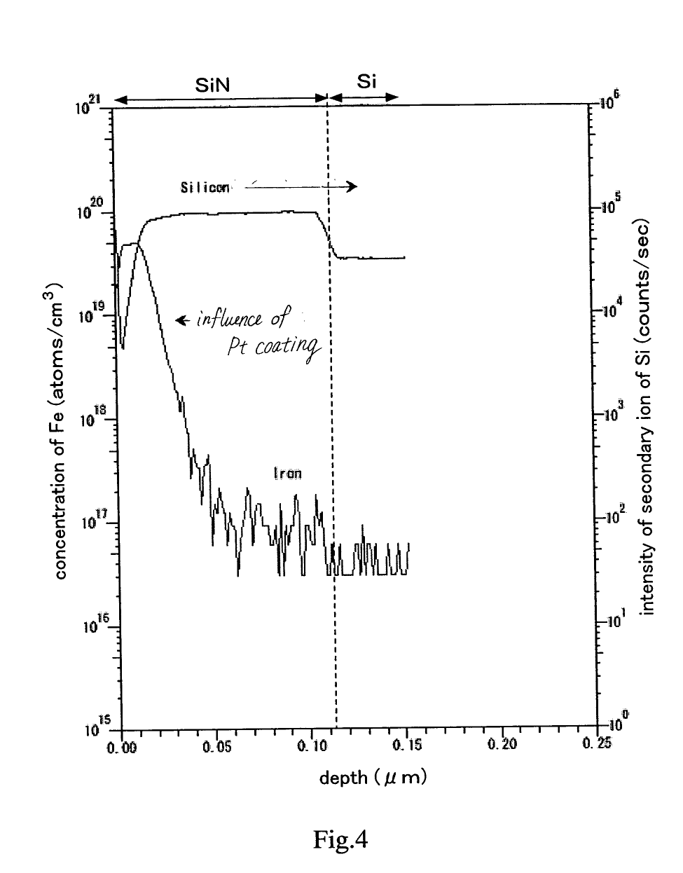

An explanation will be given with reference to FIGS. 3 and 4 on results of SIMS (secondary ion mass spectrometry), a concentration of Fe contained in each of a silicon nitride film formed in a sputtering system including a shield coated with a spray material of silicon (to which spraying is performed) according to the present invention and a silicon nitride film formed in a sputtering system including a shield that is not coated with the spray material of silicon.

In the spraying, only target shield is coated with the spray material of silicon to obtain a thickness from 60 to 80 μm. Concretely speaking, gas of Ar, He, and H₂ is flown between electrodes and voltage is applied to generate plasma, and a silicon powder is sprayed to the target shield. Roughness of the surface has Ra from 3.5 to 4 μm and Rz from 21 to 24 μm.

FIGS. 3 and 4 show graphs in which data points are connected with a smoothing line, and a horizontal axis, a left vertical axis, and a right vertical axis show a depth (μm), a concentration of Fe (atoms/cm³), and an intensity of a secondary ion of silicon (counts/sec) respectively in each of FIGS. 3 and 4. FIG. 3 shows the result of the silicon nitride film formed in the sputtering system including the shield coated with the spray material of silicon according to the present invention, and FIG. 4 shows the result of the silicon nitride film formed in the sputtering system including the shield that is not coated with the spray material of silicon.

As understood from FIGS. 3 and 4, the concentrations of Fe are greatly different from each other particularly in the range from 0 to 0.02 μm in depth, that is, the silicon nitride film formed in the sputtering system including the shield coated with the spray material of silicon according to the present invention has a lower concentration of Fe, and a noticeable effect of the present invention is particularly figured out.

Accordingly, when a thin film is formed with a sputtering system according to the present invention, a concentration of an impurity contained in the thin film is reduced, and a high-quality thin film can be formed.

[Embodiment 2]

It is possible with a sputtering system according to the present invention to form a film of a display device represented by a liquid crystal display device or a light emitting device (an EL display device, for example) including a light emitting element.

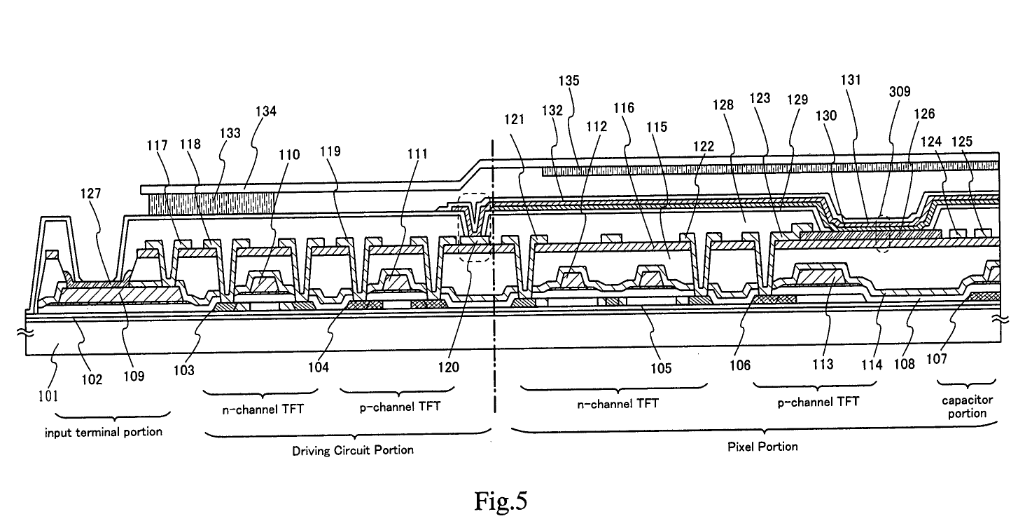

FIG. 5 shows as an example a sectional view of a light emitting device manufactured with the use of a sputtering system according to the present invention. The light emitting device has a substrate 101 such as a glass substrate or an organic resin substrate, a first insulating film 102 including an inorganic material such as silicon nitride or silicon oxynitride, semiconductor layers 103 to 107, a gate insulating film 108 including silicon oxide or silicon oxynitride, a wiring 109 and gate electrodes 110 to 113 including an element selected form Ta, W, Ti, Mo, Al, and Cu, or an alloy or a compound containing the element as its main component, a second insulating film 114 including an inorganic material such as silicon oxynitride containing hydrogen, a third insulating film 115 including an organic material such as polyimide, polyamide, acrylic, or BCB, a fourth insulating film 116 including an inorganic material such as silicon nitride, silicon oxynitride, aluminum nitride, or aluminum oxynitride, wirings 117 to 125 including a metal such as Al, Ti, Mo, or W, an anode 126 of a light emitting element 309 and a film 127 on the wiring 109 both including ITO, a fifth insulating film 128 including an organic material such as polyimide, polyamide, acrylic, or BCB, a sixth insulating film 129 including an inorganic material such as silicon nitride, or aluminum nitride, a light emitting layer 130 including an organic compound, an cathode 131 including an alkali metal or an alkali-earth metal such as Mg, Li, or Ca, a seventh insulating film 132 including an inorganic material such as silicon nitride, DLC (diamond-like carbon), aluminum oxynitride, aluminum oxide, or aluminum nitride, a sealant 133, a sealing material 134 including a glass or a metal such as stainless or aluminum, and a desiccant 135 such as barium oxide.

It is possible to refer to pending U.S. Pat. application Ser. No. 10/289,261 filed on Nov. 7, 2002 about a manufacturing method of the light emitting device shown in FIG. 5, and the fourth insulting film 116, for example, can be formed with a sputtering system according to the present invention. In this case, silicon may be used as a target of the sputtering system to coat a part such as a contamination plate of the sputtering system with a spray material including silicon, for example. It is noted that the U.S. Patent application is published as publication No. 2003/0089991 and an entire disclosure of the U.S. Patent application is incorporated herein by reference.

In addition, an amorphous semiconductor film may be formed with the use of a puttering system according to the present invention in the case of gettering to remove a metal element remaining in a crystallized semiconductor film. In this case, silicon may be used as a target of the sputtering system to coat a part such as a contamination plate of the sputtering system with a spray material including silicon. It is possible to refer to the above-mentioned U.S. patent application Ser. No. 10/289,261 or U.S. Pat. No. 5,789,284 about details of gettering, and an entire disclosure of the U.S. Pat. No. 5,789,284 is also incorporated herein by reference.

According to the present invention, it is possible to provide a sputtering system for forming a high-quality thin film including no impurity, and to provide a method for manufacturing a high-quality thin film with a sputtering system according to the present invention. In addition, according to the present invention, it is possible to form a high-quality thin film with a high yield, and furthermore to improve productivity of an element using the thin film.

What is claimed is:

1. A sputtering system comprising:
a target material;
a part coated with a spray material comprising the same material as the target material.

2. A sputtering system comprising:
a target material comprising a semiconductor material;
a part coated with a spray material comprising the semiconductor material.

3. A sputtering system comprising:
a target material comprising a semiconductor material;
a part coated with a spray material comprising one of oxide of the semiconductor material and nitride of the semiconductor material.

4. A sputtering system comprising:
a target material;
a part coated with a spray material comprising the same material as the target material,
wherein a thin film formed on a substrate provided to face the target material comprises one of the same material as the spray material, oxide of the spray material, and nitride of the spray material.

5. A sputtering system comprising:
a target material comprising a semiconductor material;
a part coated with a spray material comprising the semiconductor material;
wherein a thin film formed on a substrate provided to face the target material comprises one of the same material as the semiconductor material, oxide of the semiconductor material, and nitride of the semiconductor material.

6. A sputtering system comprising:
a target material comprising a semiconductor material;
a part coated with a spray material comprising one of oxide of the semiconductor material and nitride of the semiconductor material;
wherein a thin film formed on a substrate provided to face the target material comprises one of oxide of the semiconductor material and nitride of the semiconductor material.

7. A sputtering system according to claim 1, wherein the part is one of the group consisting of a target shield, a contamination plate, a backing plate, a current plate, a substrate holder, a gas introducing tube, and an inner wall of a chamber.

8. A sputtering system according to claim 2, wherein the part is one of the group consisting of a target shield, a contamination plate, a backing plate, a current plate, a substrate holder, a gas introducing tube, and an inner wall of a chamber.

9. A sputtering system according to claim 3, wherein the part is one of the group consisting of a target shield, a contamination plate, a backing plate, a current plate, a substrate holder, a gas introducing tube, and an inner wall of a chamber.

10. A sputtering system according to claim 4, wherein the part is one of the group consisting of a target shield, a contamination plate, a backing plate, a current plate, a substrate holder, a gas introducing tube, and an inner wall of a chamber.

11. A sputtering system according to claim 5, wherein the part is one of the group consisting of a target shield, a contamination plate, a backing plate, a current plate, a substrate holder, a gas introducing tube, and an inner wall of a chamber.

12. A sputtering system according to claim 6, wherein the part is one of the group consisting of a target shield, a contamination plate, a backing plate, a current plate, a substrate holder, a gas introducing tube, and an inner wall of a chamber.

13. A sputtering system according to claim 2, wherein the semiconductor material is silicon.

14. A sputtering system according to claim 3, wherein the semiconductor material is silicon.

15. A sputtering system according to claim 5, wherein the semiconductor material is silicon.

16. A sputtering system according to claim 6, wherein the semiconductor material is silicon.

17. A method for manufacturing a thin film comprising one of a target material, oxide of the target material, and nitride of the target material, comprising:
preparing a sputtering system comprising the target material and a part coated with a spray material comprising the same material as the target material; and
applying high-frequency power in an atmosphere including rare gas.

18. A method for manufacturing a thin film comprising one of a semiconductor material, oxide of the semiconductor material, and nitride of the semiconductor material, comprising:
preparing a sputtering system comprising a target material comprising the semiconductor material and a part coated with a spray material comprising the same material as the semiconductor material; and
applying high-frequency power in an atmosphere including rare gas.

19. A method for manufacturing a thin film comprising one oxide of a semiconductor material and nitride of the semiconductor material, comprising:
preparing a sputtering system comprising a target material comprising the semiconductor material and a part coated with a spray material comprising one of oxide of the semiconductor material and nitride of the semiconductor material; and
applying high-frequency power in an atmosphere including rare gas.

20. A method according to claim 17, wherein the part is one of the group consisting of a target shield, a contamination plate, a backing plate, a current plate, a substrate holder, a gas introducing tube, and an inner wall of a chamber.

21. A method according to claim 18, wherein the part is one of the group consisting of a target shield, a contamination plate, a backing plate, a current plate, a substrate holder, a gas introducing tube, and an inner wall of a chamber.

22. A method according to claim 19, wherein the part is one of the group consisting of a target shield, a contamination plate, a backing plate, a current plate, a substrate holder, a gas introducing tube, and an inner wall of a chamber.

23. A method according to claim 18, wherein the semiconductor material is silicon.

24. A method according to claim 19, wherein the semiconductor material is silicon.

25. A method for manufacturing a thin film comprising one of a target material, oxide of the target material, and nitride of the target material, comprising:
preparing a sputtering system comprising the target material and a part coated with a material comprising the same material as the target material; and
applying high-frequency power in an atmosphere including rare gas.

26. A method according to claim 25, wherein the part is one of the group consisting of a target shield, a contamination plate, a backing plate, a current plate, a substrate holder, a gas introducing tube, and an inner wall of a chamber.

27. A method according to claim 25, wherein the target material is silicon.

28. A method for manufacturing a semiconductor device comprising a thin film comprising one of a target material, oxide of the target material, and nitride of the target material, comprising:
forming a semiconductor film over a substrate;
forming an insulating film on the semiconductor film;
forming an electrode over the insulating film;
preparing a sputtering system comprising the target material and a part coated with a material comprising the same material as the target material; and
applying high-frequency power in an atmosphere including rare gas to form the thin film over the electrode.

29. A method according to claim 28, wherein the part is one of the group consisting of a target shield, a contamination plate, a backing plate, a current plate, a substrate holder, a gas introducing tube, and an inner wall of a chamber.

30. A method according to claim 28, wherein the target material is silicon.
